(19) United States
(12) Patent Application Publication
(10) Pub. No.: US 2021/0181235 A1
(43) Pub. Date: Jun. 17, 2021

(54) HIGH FREQUENCY PAWL SPRING PROBE APPLIED TO 5G

(71) Applicant: Suzhou UIGreen Micro&Nano Technologies Co.,Ltd., Suzhou (CN)

(72) Inventors: Xiaochen QIAN, SUZHOU (CN); Xingshun LUO, SUZHOU (CN); Zhiwei LIU, SUZHOU (CN); Yunshuai GUO, SUZHOU (CN)

(21) Appl. No.: 16/924,337

(22) Filed: Jul. 9, 2020

(30) Foreign Application Priority Data
Dec. 17, 2019 (CN) 201911299747.0
Dec. 17, 2019 (CN) 201922264953.X

(51) Int. Cl. G01R 1/067

(52) U.S. Cl. CPC G01R 1/06722; G01R 1/06772

(57) ABSTRACT

The invention provides a high-frequency pawl spring probe applied to 5G, which comprises a sleeve with a hollow cavity inside with a spring in it. There is a pawl spring at the upper end in the sleeve; the pawl spring comprises a cylindrical pawl spring cylinder and the elastic sheets at the lower end of the pawl spring cylinder; and the pawl spring cylinder is in an interference fit with the sleeve. A plunger is set in the pawl spring, and the elastic sheets are in contact with the plunger. The advantages of this invention are that: the probe structure has good directivity with small fluctuation of resistance value, which can be used in vibration or under the fluctuating external force, thus avoiding the instantaneously cut-off of the probes at present. The application range is expanded, which well meets the requirements of the equipment reliability in the 5G era.

### CROSS-REFERENCE TO RELATED APPLICATIONS

This application claims priority to Chinese Patent Applications No. CN201911299747.0 and No. CN201922264953.X with a filing date of Dec. 17th, 2019. The content of the aforementioned applications, including any intervening amendments thereto, are incorporated herein by reference.

### FIELD OF THE INVENTION

This application relates to the technical field of semiconductor components, and particularly relates to a high-frequency pawl spring probe applied to 5G.

### BACKGROUND

With the development of the domestic semiconductor industry, the demand for domestic independent R&D chips is constantly increasing, and many chips of electronic products are made abroad. Among them, a large number of micro and high-performance spring test probes are needed in the testing of high-reliability chips in production and manufacturing.

As shown in FIG. 1, the structure of common spring probe generally comprises a sleeve 1, wherein a spring 2 is set in the sleeve 1, a ball 3 is set at the upper end of the spring 2, and a plunger 4 is set in the top of the sleeve 1. when the plunger 4 is subjected to external downward pressure, the force is transmitted from the ball 3 to the spring 2 to compress and deform the spring 2. When the external pressure is removed, the spring 2 automatically resets to force the plunger 4 to return to the original position.

Due to the clearance fit between the sleeve 1 and the plunger 4 of this structure, when the plunger moves downward or upward, it will swing 360 degrees in any direction. If the external applied pressure is not linear (e.g. fluctuating or vibrating), the product will be instantaneously cut off (the plunger 4 cannot contact the inner wall of the sleeve 1), and the resistance value will be instantaneously increased, resulting in poor communication.

That is to say, the probe in the prior art is only applicable under static pressure or be used in the environment with less strict requirements on resistance value runout. It can not be used in the environment with undulation force, so it has certain limitations on use environment. With the increasing development of science and technology, there is an urgent need for a probe that can prevent the instantaneous disconnection in the vibration environment, so as to better meet the higher requirements of the 5G era on the reliability of equipment.

### BRIEF DESCRIPTION OF THE DRAWINGS

Various embodiments in accordance with the present disclosure will be described with reference to the drawings, in which:

FIG. 1 illustrates the schematic diagram of the probe structure of the prior art of the invention.

FIG. 2 illustrates the schematic diagram of the invention.

FIG. 3 illustrates the schematic diagram of the pawl spring in the invention.

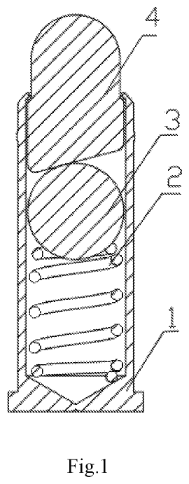

### SUMMARY OF THE INVENTION

In order to solve the defects of the prior art, the invention provides a high-frequency pawl spring probe applied to 5G.

The aim of the invention is realized by the following technical scheme:

The high frequency pawl spring probe applied to 5G comprises a sleeve with a hollow cavity inside, wherein a spring is set in the cavity; a pawl spring is set at the upper end in the sleeve; the pawl spring comprises a cylindrical pawl spring cylinder and the elastic sheets set at the lower end of the pawl spring cylinder; and the pawl spring cylinder is in an interference fit with the sleeve. A plunger is set in the pawl spring, and the elastic sheets are in contact with the plunger.

Preferably, the top end of the plunger is set outside the sleeve, and the bottom end of the plunger is in contact with the spring.

Preferably, the plunger comprises a guide post, the bottom of the guide post is connected with a conical pressing part, and the pressing part is set below the elastic sheets.

Preferably, a clearance is set between adjacent elastic sheets.

Preferably, the diameter of the bottom opening enclosed between the elastic sheets is equivalent to the diameter of the guide post.

Preferably, the upper end of the guide post is set with a columnar compression end, and the top of the compression end is set with a spherical surface.

Preferably, the diameter of the upper end of the pressing part is larger than the diameter of the guide post, and the diameter of the lower end of the columnar compression end is larger than the diameter of the guide post.

Preferably, the columnar compression end is in clearance fit with the pawl spring cylinder.

Preferably, the bottom of the cavity is tapered.

The advantages of this invention are that: the probe structure has good directivity with small fluctuation of resistance value, which can be used in vibration or under the fluctuating external force, thus avoiding the instantaneously cut-off of the probes at present. The application range is expanded, which well meets the requirements of the equipment reliability in the 5G era.

### DETAILED DESCRIPTION OF THE INVENTION

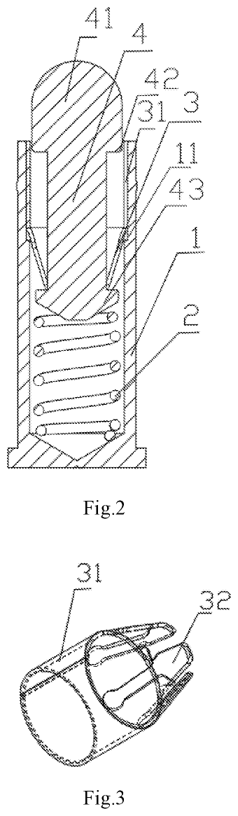

The technical scheme of the invention was described in detail with reference to embodiment. The invention discloses a high frequency pawl spring probe applied to 5G, as shown in FIGS. 2-3. The probe comprises a sleeve 1 with a hollow cavity inside, and the bottom of the cavity is tapered. The spring 2 is set in the cavity, and the spring 2 is in a clearance fit with the sleeve 1, that is, there is a clearance between the spring 2 and the sleeve 1, so that the spring 2 can freely deform in the sleeve 1.

The upper end in the sleeve 1 is set with a pawl spring 3, and the pawl spring 3 comprises a cylindrical pawl spring cylinder 31 and an elastic sheet 32 set at the lower end of the pawl spring cylinder 31. In order to firmly connect the pawl spring 3 with the sleeve 1, the pawl spring cylinder 31 and the sleeve 1 adopt interference fit. There is a clearance between the adjacent elastic sheets32 , and the number limit of the elastic sheets can be selected as required. In this embodiment, there are six elastic sheets, and the elastic sheets are tapered, that is, the bottom of the elastic sheets 32 and the inner cavity of the sleeve 1 maintain a clearance without contact. In order to further ensure the high stability of the pawl spring position, a limiting table 11 is set in the cavity of the sleeve 1, which divides the cavity into two parts, the diameter of the upper part is larger than the diameter of the lower part, and the pawl spring cylinder 31 and the upper part of the cavity are in interference fit.

The pawl spring is set with a plunger, the top end of the plunger is set outside the sleeve, and the bottom end of the plunger is in contact with the spring 2. Specifically, the plunger comprises a guide post 4, the bottom of which is connected with a conical pressing part 43, the diameter of the upper end of the pressing part 43 is larger than the diameter of the guide post 4, and the pressing part 43 is set below the elastic sheets 32.

The upper end of the guide post 4 is set with a columnar compression end 41, and the top of the compression end 41 is set with a spherical surface. The diameter of the lower end 42 of the compression end 41 is larger than the diameter of the guide post 4. The height of the compression end 41 exposed from the sleeve 1 is smaller than the height of the pawl spring cylinder 31 to ensure the stroke of the compression end 41. The compression end 41 is in clearance fit with the pawl spring cylinder 31. Meanwhile, in order to ensure the close contact between the plunger and the spring 2, the diameter of the bottom opening enclosed between the elastic sheets 3 is equivalent to the diameter of the guide post 4, so that the pressing part 43 is kept under the elastic sheets 3.

With above settings, the plunger and the inner wall of sleeve the can always maintain indirect contact regardless of the vibration environment or the application of fluctuating external force, thus avoiding the instantaneous cut-off of the existing probe.

The following briefly describes the assembly process of the spring probe of the present invention:

Firstly, place the spring 2 in the cavity of the sleeve 1, then put the pawl spring in the cavity, and finally put the plunger in the pawl spring. When the compression end 41 is pressed, the plunger moves downward to press the spring, and when the pressure is removed, the spring returns, forcing the plunger to return to the initial position.

The upper end, lower end and other directional limiting words in the this invention are only referred to in the drawings of the invention and are not regarded as absolute limitations.

There are still many specific implementations of the this invention, which are not be listed here. All technical solutions by equivalent substitution or equivalent transformation are within the scope of the invention.

We claims:

1. A high frequency pawl spring probe applied to 5G, comprising:
a sleeve with a hollow cavity inside; wherein a spring is in the cavity, there is a pawl spring at the upper end in the sleeve; the pawl spring comprises a cylindrical pawl spring cylinder and the elastic sheets at the lower end of the pawl spring cylinder; and the pawl spring cylinder is in an interference fit with the sleeve; a plunger is set in the pawl spring, and the elastic sheets are in contact with the plunger.

2. The high frequency pawl spring probe applied to 5G of claim 1, wherein:
the top end of the plunger is set outside the sleeve, and the bottom end of the plunger is in contact with the spring.

3. The high frequency pawl spring probe applied to 5G of claim 2, wherein:
the plunger comprises a guide post, the bottom of the guide post is connected with a conical pressing part, and the pressing part is set below the elastic sheets.

4. The high frequency pawl spring probe applied to 5G of claim 1, wherein:
a clearance is set between adjacent elastic sheets.

5. The high frequency pawl spring probe applied to 5G of claim 3, wherein:
the diameter of the bottom opening enclosed between the elastic sheets is equivalent to the diameter of the guide post.

6. The high frequency pawl spring probe applied to 5G of claim 3, wherein:
a columnar compression end is set at the upper end of the guide post, and the top of the compression end is set with a spherical surface.

7. The high frequency pawl spring probe applied to 5G of claim 6, wherein:
the diameter of the upper end of the pressing part is larger than the diameter of the guide post, and the diameter of the lower end of the columnar compression end is larger than the diameter of the guide post.

8. The high frequency pawl spring probe applied to 5G of claim 6, wherein:
the columnar compression end is in clearance fit with the pawl spring cylinder.

9. The high frequency pawl spring probe applied to 5G of claim 1, wherein:
the bottom of the cavity is tapered.
